(19) United States
(12) Patent Application Publication
(10) Pub. No.: US 2025/0236944 A1
(43) Pub. Date: Jul. 24, 2025

(54) SYSTEMS, COMPOSITIONS AND METHODS FOR METAL OXYNITRIDE DEPOSITION USING HIGH-BASE PRESSURE REACTIVE SPUTTERING

(71) Applicant: Massachusetts Institute of Technology, Cambridge, MA (US)

(72) Inventors: Jatin Jayesh PATIL, Cambridge, MA (US); Jeffrey C. GROSSMAN, Cambridge, MA (US)

(21) Appl. No.: 18/697,974

(22) PCT Filed: Nov. 30, 2022
(86) PCT No.: PCT/US2022/051461

§ 371 Date: Apr. 2, 2024

Related U.S. Application Data
(60) Provisional application No. 63/284,210, filed on Nov. 30, 2021.

(51) Int. Cl. C23C 14/06; C23C 14/00

(52) U.S. Cl. CPC C23C 14/0676; C23C 14/0036

(57) ABSTRACT

Systems, compositions, and methods for using reactive magnetron sputtering to encapsulate nanowire networks to improve their chemical, thermal, and electrical stability while maintaining transparency are disclosed. For example, oxynitride films are deposited onto silver nanowire networks using full-metal targets without imparting oxidative damage onto the nanowires. The oxynitrides can be deposited using residual water vapor in the chamber that can take advantage of relatively poor vacuum conditions, which would be compatible with high-volume roll-to-roll sputtering approaches, and would also reduce the cost of encapsulating sensitive metal nanostructures which would encounter high temperatures, currents, or humidity. The resulting films can be applicable in a wide variety of fields as transparent encapsulants, where metal nanostructures would need to be protected from harsh environmental conditions and/or high temperatures-including but not limited to: solar cell electrodes, transparent heaters, touch screens, and LEDs.

### CROSS REFERENCE TO RELATED APPLICATION

The present disclosure claims priority to and the benefit of U.S. Provisional Application No. 63/284,210, entitled “Metal Oxynitride Deposition Using High-Base Pressure Reactive Magnetron Sputtering,” filed on Nov. 30, 2021, the content of which is incorporated by reference herein in its entirety.

### FIELD

The present disclosure relates to systems, compositions, and methods for encapsulating nanowire networks with oxynitride films, and more particularly relates to systems, compositions, and methods for using reactive magnetron sputtering to deposit oxynitride films onto silver nanowire networks using full-metal targets without imparting oxidative damage onto the nanowires.

### BACKGROUND

In the past few decades, transparent electrodes (TEs) have been of significant technological importance due to their prevalence in a wide range of optoelectronic applications such as transparent heaters, solar cell electrodes, displays, light-emitting diodes (LEDs), sensors, and electromagnetic-interference shielding, among others. For most of these applications, transparent conductive oxides (TCOs) have prevailed as the predominant material in commercial applications. More particularly, indium tin oxide (ITO) has been a popular choice due to its high optical transmittance (90% at 550 nm) and low sheet resistance (20 Ω/sq). However, TCOs have largely been limited in their implementation either due to their poor mechanical stability or for their low direct current (DC)-to-optical conductivity ratio, which is a metric that describes their tradeoff between sheet resistance and optical transparency. Moreover, recent issues concerning the supply risk of indium globally have expedited the search for alternative TE technology.

Silver nanowire (AgNW) networks have been explored as a promising technology for transparent electrodes due to their solution-processability, low-cost implementation, and excellent trade-off between sheet resistance and transparency. Metal nanowires, nanogrids, and nanotroughs are examples of alternative TE technologies that rely on percolative networks of metal, typically Ag or Cu, which exhibit transparency and sheet resistance since the majority of the film area is comprised of empty voids. In the specific case of solution-synthesized AgNWs, transparencies of 80-90% at 550 nm, and sheet resistances approaching 10 Ω/sq can be achieved, which is sufficient for most of the aforementioned applications.

AgNW networks have several shortcomings that hinder their widespread implementation in industrial applications. For example, AgNW networks exhibit poor thermal, electrical, and chemical stability due, at least in part, to their high surface-to-volume ratios, which prevents their large-scale implementation. Chemical degradation occurs primarily through sulfidation, which causes Ag to transform into Ag₂S particles, through reactions with atmospheric sulfur species such as carbonyl sulfide (OCS), and is exacerbated by elevated temperatures and humidity. Failure can also occur through localized Joule heating under electrical stresses, which can cause accelerated surface diffusion and surface-area minimization to occur-processes that ultimately cause disconnection of wire junctions, and, under high temperatures, full spheroidization of nanowires through the Rayleigh instability mechanism.

While solution-based methods for applications like photovoltaics are promising and often cited as low-cost methods, most are processing-intensive and slow, which limits high-throughput production applications. Meanwhile, other methods under development, such as spatial atomic layer deposition, require new hardware innovation, integration, and scale up, which limits its immediate applicability for most existing infrastructures.

Accordingly, there is a need to develop systems and methods for manufacture of transparent electrodes that improves their thermal, electrical, and/or chemical stability without imparting oxidative damage thereto.

### SUMMARY

The present application is directed to systems, compositions, and methods for forming transparent electrodes (TEs) using reactive sputtering for fast deposition of metal oxynitrides as an encapsulant layer on nanowire networks. For example, solution-synthesized silver nanowires (AgNWs) can be encapsulated in oxynitride films via reactive magnetron sputtering using full-metal targets to coat the AgNWs to improve their chemical, thermal, and electrical stability while avoiding oxidative damage onto the nanowires. In some embodiments, a reactive gas can be used under high sputtering base pressures to leverage residual water (H₂O) on the sample and chamber to deposit aluminum (Al), titanium (Ti), and zirconium (Zr) oxynitrides (AlOₓN_{y}, TiOₓN_{y}, ZrOₓN_{y}) on Ag nanowires on glass and polymer substrates. The sputtering methods can be compatible with roll-to-roll processes that can be operated at commercial scales, and this technique can be extended, for example, to arbitrary, vacuum-compatible substrates and device architectures.

One exemplary embodiment of an electrode device includes a substrate material, a solution-phase wire material, and an encapsulant film disposed on a surface of the solution-phase wire material. The encapsulant film includes a sputtered oxynitride, the sputtered oxynitride including a metal and nitrogen. A linear resistance of the solution-phase wire material having the encapsulant film disposed on its surface is less than a linear resistance of the solution-phase wire material having no encapsulant film disposed on its surface.

The substrate material can include one or more of glass, silicon, or polyethylene terephthalate (PET). A form factor of the solution-phase wire material can be approximately in a range of about 20 nm to about 200 nm. The solution-phase wire material can contain one or more of Ag or Cu nanowires, Ag or Cu nanotroughs, or lithographically patterned Ag or Cu micro- or nano-structures. A thickness of the encapsulant film can be approximately in a range of about 0 nm to about 100 nm.

The oxynitride can include one or more of AlOₓN_{y}, TiOₓN_{y}, or ZrOₓN_{y}. A percentage of the nitrogen in the encapsulant film can be approximately in a range of about 0% of a total atomic composition of the film to about 30% of a total atomic composition of the film.

A thermal stability of the electrode device can be approximately 100° C. above a failure point of an electrode device that lacks an encapsulant film disposed on a surface of the solution-phase wire material. An electrical stability with applied linear voltages for the electrode device can be about 7.87 V/cm without resistance. In some embodiments, an electrical stability with applied linear voltages for the electrode device can be approximately 1.66 times larger than an electrode device that lacks an encapsulant film disposed on a surface of the solution-phase wire material. A chemical stability of the electrode device can have an increase in linear resistance that is approximately fifty times smaller than an electrode device that lacks an encapsulant film disposed on a surface of the solution-phase wire material.

In one exemplary embodiment of a method of manufacturing a transparent electrode, the method includes sputtering a metal target material with one or more gases, at least one of which includes nitrogen, in a sputtering chamber to eject one or more solid particles of the metal target material, reacting the one or more solid particles with the one or more gases to form a resulting material, and depositing the resulting material onto a substrate having one or more nanowires disposed thereon, the resulting material forming a film when deposited onto the substrate having one or more nanowires disposed thereon. The resulting material conforms to one or more of the substrate or the nanowires to surround the one or more of the substrate or the nanowires at least across a circumference of the nanowires.

The method can further include conditioning the nanowires prior to sputtering by removing a portion of one or more compounds from a surface thereof. The one or more compounds can include poly(vinylpyrrolidone) (PVP). Conditioning can include at least one of vacuum or plasma exposure. Sputtering can further include one or more of direct-current sputtering, reactive magnetron sputtering, radio-frequency magnetron sputtering, or intermittent arc DC sputtering.

The sputtering can occur at high base pressures to leverage the residual water vapor on the nanowires or within the sputtering chamber. The high base pressures can be approximately in a range of about 10⁻³ to about 10⁻⁶ Torr. The one or more gases can include one or more of argon (Ar), nitrogen (N₂), oxygen (O₂^{¬}), or water (H₂O). The metal target can include one or more of aluminum (Al), titanium (Ti), zirconium (Zr), zinc (Zn), hafnium (Hf), silicon (Si), metalloids, semiconductors, alloys, or combinations thereof.

The resulting material can be directly deposited onto one or more of the substrate or the nanowires as an encapsulant configured to prevent damage thereto. The resulting material can be deposited using residual water vapor in the sputtering chamber. The resulting material can be deposited with a substrate temperature approximately in the range of about 298 K to about 900 K. In some embodiments, the resulting material can be deposited with no external heating applied to the substrate.

In another exemplary embodiment of an electrode device, the electrode device includes a substrate material; a solution-phase wire material; and an encapsulant film applied to the solution-phase wire material. The encapsulant film includes an oxynitride formed by sputtering a metal target with nitrogen gas, the film forming on a surface of the solution-phase wire material when applied thereto. A linear resistance of the solution-phase wire material having the encapsulant film applied thereto decreases after the encapsulant film is applied thereto.

The substrate material can include one or more of glass, silicon, or polyethylene terephthalate (PET). A form factor of the solution-phase wire material can be approximately in a range of about 20 nm to about 200 nm. The solution-phase wire material can contain one or more of Ag or Cu nanowires, Ag or Cu nanotroughs, or lithographically patterned Ag or Cu micro- or nano-structures. A thickness of the encapsulant film can be approximately in a range of about 0 nm to about 100 nm.

The oxynitride can include one or more of AlOₓN_{y}, TiOₓN_{y}, or ZrOₓN_{y}. A percentage of the nitrogen in the encapsulant film can be approximately in a range of about 0% of a total atomic composition of the film to about 30% of a total atomic composition of the film.

A thermal stability of the electrode device can be approximately 100° C. above a failure point of an electrode device that lacks an encapsulant film disposed on a surface of the solution-phase wire material. An electrical stability with applied linear voltages for the electrode device can be about 7.87 V/cm without resistance. In some embodiments, an electrical stability with applied linear voltages for the electrode device can be approximately 1.66 times larger than an electrode device that lacks an encapsulant film disposed on a surface of the solution-phase wire material. A chemical stability of the electrode device can have an increase in linear resistance that is approximately fifty times smaller than an electrode device that lacks an encapsulant film disposed on a surface of the solution-phase wire material.

### BRIEF DESCRIPTION OF THE DRAWINGS

This disclosure will be more fully understood from the following detailed description taken in conjunction with the accompanying drawings, in which:

FIG. 1A is a schematic diagram of one embodiment of a sputtering process of the present disclosure that include a conditioning step followed by a step of oxynitride deposition via sputtering;

FIG. 1B is a schematic diagram of the sputtering process of FIG. 1A showing a deposition process in a sputtering chamber;

FIG. 1C is a schematic perspective view of a nanowire network formed by the sputtering process of FIG. 1B;

FIG. 2A is a scanning electron microscope (SEM) image of perspective plan view of an untreated silver nanowire (AgNW);

FIG. 2B is an SEM image of a front cross-section view of an untreated AgNW;

FIG. 2C is an SEM image of a perspective plan view of an AgNW encapsulated with a 20 nm aluminum oxynitride (AlON) film;

FIG. 2D is an SEM image of a front cross-section view of an AgNW encapsulated with a 20 nm AlON film;

FIG. 2E is an SEM image of a perspective plan view of an AgNW encapsulated with a 50 nm AlON film;

FIG. 2F is an SEM image of a front cross-section view of an AgNW encapsulated with a 50 nm AlON film;

FIG. 3A is a photograph of a perspective view of a glass substrate that forms the TE;

FIG. 3B is a photograph of a perspective view of the glass substrate of FIG. 3A having an AgNW disposed thereon;

FIG. 3C is a photograph of a perspective view of the glass substrate with the AgNW of FIG. 3B encapsulated with a 20 nm AlON film;

FIG. 3D is a photograph of a perspective view of the glass substrate with the AgNW of FIG. 3B encapsulated with a 50 nm AlON film;

FIG. 3E is a photograph of a perspective view of the glass substrate with the AgNW of FIG. 3B encapsulated with a 20 nm zirconium oxynitride (ZrON) film;

FIG. 3F is a photograph of a perspective view of the glass substrate with the AgNW of FIG. 3B encapsulated with a 50 nm ZrON film;

FIG. 3G is a photograph of a perspective view of the glass substrate with the AgNW of FIG. 3B encapsulated with a 20 nm titanium oxynitride (TiON) film;

FIG. 3H is a photograph of a perspective view of the glass substrate with the AgNW of FIG. 3B encapsulated with a 50 nm TiON film;

FIG. 3I is a photograph of a perspective view of another embodiment of the AgNW encapsulated with a 20 nm AlON film disposed on a flexible polymer;

FIG. 3J is a photograph of a perspective view of the TE of FIG. 3I being bent;

FIG. 3K is a graph illustrating transmittance spectra of untreated AgNWs and AgNWs encapsulated with the 20 nm films of FIGS. 3C, 3E, and 3G;

FIG. 3L is a graph illustrating transmittance spectra of untreated AgNWs and AgNWs encapsulated with the 50 nm films of FIGS. 3D, 3F, and 3H;

FIG. 4A is a graph illustrating progression of normalized resistance values for untreated AgNWs and AgNW films encapsulated with the 20 nm films of FIGS. 3C, 3E, and 3G film under conditions including about 80° C. and about 80% relative humidity (RH);

FIG. 4B is a graph illustrating progression of normalized resistance values for untreated AgNWs and AgNW films encapsulated with the 50 nm films of FIGS. 3D, 3F, and 3H film under conditions including about 80° C. and about 80% RH;

FIG. 4C is an SEM image of a magnified perspective view of untreated AgNWs after six (6) days of testing;

FIG. 4D is an SEM image of a magnified perspective view of ZrON-coated AgNWs after seven (7) days of testing;

FIG. 4E is an SEM image of a magnified perspective view of TiON-coated AgNWs after six (6) days of testing;

FIG. 4F is an SEM image of a magnified perspective view of AlON-coated AgNWs after 40 days of testing;

FIG. 5A is a graph illustrating temperature versus thermally adjusted, normalized resistance (TANR) values of sample hotplate-heated nanowires versus sample furnace-heated nanowires of the present embodiments;

FIG. 5B is a schematic diagram of a hotplate heating method for testing of AgNW film samples of the present embodiments;

FIG. 5C is a schematic diagram of a furnace heating method for testing of AgNW film samples of the present embodiments;

FIG. 6A is a graph illustrating TANR values of untreated AgNWs and AgNW networks coated with the 20 nm films of FIGS. 3C, 3E, and 3G thermally ramped at about 6.25° C./min;

FIG. 6B is a graph illustrating TANR values of untreated AgNWs and AgNW networks coated with the 50 nm films of FIGS. 3D, 3F, and 3H thermally ramped at about 6.25° C./min;

FIG. 6C is a graph illustrating normalized resistance of untreated AgNWs and AgNW networks coated with the 20 nm films of FIGS. 3C, 3E, and 3G ramped at about 0.5 V/min; and

FIG. 6D is a graph illustrating normalized resistance of untreated AgNWs and AgNW networks coated with the 50 nm films of FIGS. 3D, 3F, and 3H ramped at about 0.5 V/min.

### DETAILED DESCRIPTION

Certain exemplary embodiments will now be described to provide an overall understanding of the principles of the structure, function, manufacture, and use of the systems, devices, and methods disclosed herein. One or more examples of these embodiments are illustrated in the accompanying drawings. Those skilled in the art will understand that the systems, compositions, and methods specifically described herein and illustrated in the accompanying drawings are non-limiting exemplary embodiments and that the scope of the present disclosure is defined solely by the claims. The features illustrated or described in connection with one exemplary embodiment may be combined with the features of other embodiments. Such modifications and variations are intended to be included within the scope of the present disclosure. Like-numbered components and/or data across embodiments generally have similar features unless otherwise stated or a person skilled in the art would appreciate differences based on the present disclosure and/or his/her knowledge. Accordingly, aspects and features of every embodiment may not be described with respect to each embodiment, but those aspects and features are applicable to the various embodiments unless statements or understandings are to the contrary.

To the extent that the present disclosure includes various terms for components and/or processes of the disclosed systems, methods, and the like, one skilled in the art, in view of the claims, present disclosure, and knowledge of the skilled person, will understand such terms are merely examples of such components and/or processes, and other components, designs, processes, and/or actions are possible. By way of non-limiting example, the terms “encapsulant” and “film” can be used interchangeably to refer to the oxynitride layer added to the nanowire network as a result, for example, of the sputtering process of the present embodiments. Further, to the extent features, sides, or steps are described as being “first” or “second,” such numerical ordering is generally arbitrary, and thus such numbering can be interchangeable. Still further, in the present disclosure, like-numbered components of various embodiments generally have similar features when those components are of a similar nature and/or serve a similar purpose. Lastly, the present disclosure includes some illustrations and descriptions that include prototypes or bench models. A person skilled in the art will recognize how to rely upon the present disclosure to integrate the techniques, systems, devices, and methods provided for into a product in view of the present disclosures.

At least one novel aspect of the present disclosure includes deposition of metal oxynitride via sputtering onto silver nanowire networks to encapsulate the networks. For example, reactive sputtering can be used as a method for fast deposition of metal oxynitrides as an encapsulant layer on silver nanowires (AgNWs). The oxynitride films can be deposited from full-metal targets at high base pressures to prevent oxidative damage onto the nanowires. The oxynitrides can be deposited using residual water vapor in the chamber, thereby allowing the presently disclosed methods to take advantage of relatively poor vacuum conditions, which would be compatible with high-volume, roll-to-roll sputtering approaches, and reduce the cost of encapsulating sensitive metal nanostructures that would encounter high temperatures, currents, and/or humidity. The resulting films can be applicable in a wide variety of fields as transparent encapsulants, where metal nanostructures can benefit from being protected from harsh environmental conditions and/or high temperatures, including but not limited to solar cell electrodes, transparent heaters, touch screens, and/or LEDs.

### Fabrication and Structural Characterization

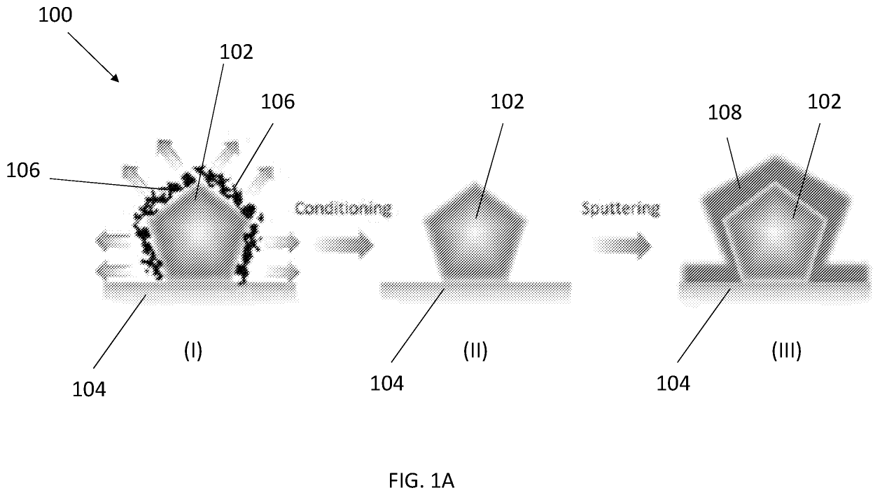

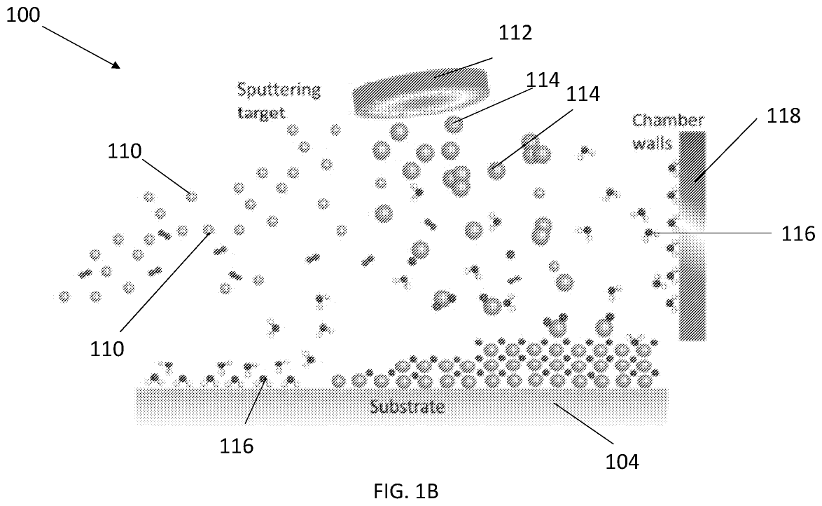

FIGS. 1A-1B illustrate one embodiment of a method of fabrication of a nanowire network 100 via sputtering. Nanowire networks can be fabricated by depositing solution-phase wires or solution-phase wire material 102 onto an arbitrary substrate 104. The substrate 104 can be flexible and/or include, for example, one or more of glass, silicon, or polyethylene terephthalate (PET) to support the wires 102 thereon. A form factor of the AgNW can be approximately in a range of about 20 nm to 200 nm in width or diameter. A length of the AgNW can be approximately in a range of about 10 microns to about 200 microns. For the purpose of this disclosure, the terms “nanorods” and/or “nanocylinders” can be used in place of the term “nanowires,” with the understanding that a purpose of the nanowire structure, regardless of which term is used, is to form an electrically percolating network for a transparent electrode.

Conventional reactive sputtering deposition with oxygen used as a reactive gas onto silver or copper nanowires can destroy the silver or copper thereon via corrosion. Further, conventional sputtering processes have used nonreactive targets such as ceramics, but these have inferior deposition rates, require radio-frequency (RF) operation, and are thus prone to mechanical failure. When using a bonded ceramic target, which can directly deposit oxides, the target operates in RF mode to avoid charging, meaning that the material deposition rate can be at most half of that compared to direct current (DC) operation at the same deposition power. Further still, mechanical failure can occur if the non-conductive ceramic target builds up excessive electrical stress, which results in thermal stress that can cause failure of the bonding interface between the target material and backing. In such a failure mode, the target can be destroyed, and in worse cases, the sputtering hardware can also suffer damage. Thus, it can be desirable to use metallic targets that are much more resilient to the aforementioned failure modes at least because they do not require bonding and/or are much more resistant to electrical charge buildup and thermal stresses.

As shown in FIG. 1A, a precursor to sputtering of nanowire networks can occur via a conditioning step, e.g., from (I) to (II), in which one or more compounds 106 can be removed from the nanowires 104 due to vacuum and/or plasma exposure. Conditioning can occur in a sputtering chamber, e.g., chamber 118 of FIG. 1B, or another vessel known to one skilled in the art to facilitate sputtering of materials disposed therein. Some non-limiting examples of the compounds that can be removed during conditioning can include polyvinylpyrrolidone (PVP), polymethylmethacrylate (PMMA), hexadecylamine (HDA), octadecylamine (ODA), sodium citrate, dodecanethiol, decanethiol, among other compounds that can be categorized as “capping agents” for silver and copper nanoparticle and nanowire synthesis. The one or more compounds can be at least partially removed, though, in some embodiments, all or substantially all of the compound can be removed. A person skilled in the art will recognize that for the purpose of this disclosure, the term “substantially” can be defined as more than 80%, more than 90%, more than 95%, and/or more than 99%.

When a metal nanowire (MNW) solution is deposited on a substrate, this can result in the formation of a conductive film, which can include a network of intersecting MNWs. The intersections of MNWs, or junctions, can be fused through a variety of processing techniques to improve the conductivity of the film. The electrical and optical properties of MNW networks can be driven by the properties of the MNW segments and the properties of junctions between them, as well as their architecture, layout, and/or position. MNW films can therefore be considered a randomly interconnected electrical percolation network composed of these components. This representation is useful to be able to model the electrical behavior of these networks. Indium tin oxide (ITO) and other transparent conductive oxides (TCOs) can be deposited as continuous films across a device, and their light absorption can be dictated simply by the material and the film thickness. Alternatively, or additionally, because the areal coverage of nanowires in an MNW network is relatively low, the optical response of the network can be governed mostly by the empty spaces between the wires, which can cause the network to have good transparency across the entire optical spectrum. As the areal mass density of the nanowires increases, both the sheet resistance and optical transmittance of the network can decrease.

Stability of MNWs can be improved, for example, by the addition of an encapsulant, which can delay network degradation at least by: i) preventing the morphological evolution of MNWs caused by thermally induced atomic diffusion; ii) allowing re-distribution of heat or electrical current away from the MNWs; and/or iii) preventing the diffusion of corrosive gaseous species to the MNWs. With a slight addition of processing complexity in the system, the stability and electrical properties of MNW encapsulant composites can be improved significantly.

The addition of an encapsulant 108 is shown in the transition from (II) to (III) in FIG. 1A. For example, once conditioning of the nanowires has occurred, an oxynitride film 108 can be directly deposited onto the wires as an encapsulant to prevent oxidative damage onto the nanowires, improve electrical, thermal, and/or chemical stability, and/or optically tune the film to induce reflective, scattering, anti-reflective, and/or absorptive properties, as desirable for the particular electrode application. In some embodiments, the encapsulant can be used to interface device layers for further electrical and/or electronic functionality, such as a dielectric, a capacitive layer, and/or a conductive layer for selective electron-hole and/or electron conductance. Deposition of the oxynitride films can occur via sputtering, which is a phenomenon in which microscopic particles of a solid material can be ejected from its surface after the material itself is bombarded by energetic particles of a plasma or a gas. Specifically, when energetic ions of the plasma and/or gas collide with atoms of a target material, an exchange of momentum can take place between them that dislodges the particle of the solid material from the surface. The sputtering can be any of direct-current sputtering, reactive magnetron sputtering, radio-frequency magnetron sputtering, and/or intermittent arc DC sputtering, with a person skilled in the art recognizing the variations of each sputtering method, as well as other sputtering techniques that may also be employed. A thickness of the resulting sputtered oxynitride can be approximately in a range of about 0 nm to about 100 nm. Some non-limiting examples of the gas used for sputtering can include argon (Ar), nitrogen (N₂), oxygen (O₂^{¬}), and/or water (H₂O).

Encapsulants of the present embodiments can improve electrical, thermal, and/or chemical stability of the AgNW networks. In particular, AlOₓN_{y}-encapsulated networks can present exceptional chemical stability (negligible increase in resistance over seven (7) days at about 80% relative humidity (RH) and about 80° C.) and transparency (about 96% for 20 nm films on AgNWs), while TiOₓN_{y} can demonstrate exceptional thermal and electrical stability (stability up to oven temperatures of about 100° C. more than bare AgNW networks, with a maximum areal power density of about 1.72 W/cm², and no resistance divergence at up to about 20 V) and ZrOₓN_{y} can present intermediate properties in all metrics.

Magnetron sputtering can be employed in large-scale, roll-to-roll manufacturing, and, as provided for herein, can circumvent the issue of low deposition rates and poor target durability associated with ceramic sputtering targets. Magnetron sputtering is a high-rate vacuum coating technique that allows the deposition of many types of materials, including metals and ceramics, onto substrate materials. The surface of the target is eroded by high-energy ions within the plasma, and the liberated atoms travel through the vacuum environment and deposit onto a substrate to form a thin film. Deposition of the materials occurs by the use of a specially formed magnetic field applied to the sputtering target. These magnets can confine the electrons in the plasma at or near the surface of the target, which may lead to a higher density plasma, increased deposition rates, and prevention of damage which would be caused by direct impact of these electrons with the substrate or growing film.

In reactive magnetron sputtering, the liberated atoms react with the high-energy ions prior to being deposited onto the substrate to form the film. Reactive sputtering of materials in the present embodiments can be performed from full-metal targets of one or more of aluminum (Al), titanium (Ti), zirconium (Zr), zinc (Zn), hafnium (Hf), silicon (Si), and/or other metals, metalloids, and/or semiconductors that can be sputtered, as well as alloys and/or combinations of the elements discussed above or otherwise known to those skilled in the art. For effective deposition rates of oxynitrides, the full-metal targets can be bombarded by one or more of the gases discussed above, e.g., argon (Ar), nitrogen (N₂), oxygen (O₂), and/or water (H₂O). A fraction of the N₂ in the flow of the gas can vary. For example, in some embodiments, the fraction of N₂ in the Ar+N₂ flow can be approximately in a range of about 0 to about 0.8. An atomic or molar percentage, or atomic number percentage, of the N in the oxynitride film can be approximately in a range of about 0% of a total atomic composition to about 30% of a total atomic composition. The atomic number percentage can be measured through X-ray photoelectron spectroscopy or could be measured through energy-dispersive x-ray detection (EDX).

FIG. 1B illustrates the sputtering process in greater detail. As shown, gas particles 110 can bombard a surface of the target material 112 to eject particles of said material 114 onto the substrate 104 to form the nanowire network 113. As noted above, water particles 116 can be present within the chamber 118 such that the oxynitride, or resulting material, can be deposited using residual water vapor in the chamber 118 to allow for oxynitride film formation. In magnetron sputtering-deposited coatings of the present embodiments, the morphology of the films around the wires can be highly conformal and can encapsulate both the substrate 104 and the AgNWs 102. For example, the encapsulant 108 can conform to the substrate 104 and the nanowires 102 to surround the substrate 104 and the nanowires 102 across a circumference thereof. By comparison, conventional sputtering techniques can exhibit uneven deposition, e.g., a higher deposition of substances can be observed on top of the wires following application. Moreover, conventional films cannot sputter small components due, at least in part, to lack of granular control over the location at which sputtered particles are deposited. An example of the nanowire network 113 having a plurality of intersecting AgNWs 102 that can be formed as a result of the sputtering process discussed in FIG. 1B above is shown in FIG. 1C.

The encapsulant 108 of the present embodiments can be deposited at a deposition power that can be approximately in a range of about 100 W to about 200 W. During sputtering, the particles 114 can be deposited at a substrate temperature that is approximately in a range of about 298 K to about 900 K, though, in some embodiments, the material can be deposited with no external heating applied to the substrate 104.

Introduction of the gas particles 110 can have at least two purposes in the sputtering techniques of the present embodiments. One is such that the gas can be used to introduce the reactive species to facilitate sputtering and reaction of the reactive species to form the oxynitride film 108 that is deposited onto the AgNW. For example, the gas particles, e.g., N₂ because oxygen cannot typically be used as a reactive gas in the presence of oxidation-sensitive materials, can react with the particles of the full-metal targets 112, e.g., aluminum, to form the oxynitride, e.g., AlOₓN_{y}. Some additional non-limiting examples of oxynitrides that can be used in the present embodiments can include TiOₓN_{y} and/or ZrOₓN_{y}, which can be formed based, at least in part, on the type of metal target and/or gas that is used.

A second purpose of the gas particles can be to reduce the mean free path of the deposition of the film. For example, in the absence of gas particles, the rate of deposition can be quick such that the target particles 114 can be deposited over the AgNW, which can cause corrosion and/or damage. Use of the gas particles 110 can slow down the deposition onto the AgNW such that the sputtered particles form a transparent film when deposited onto the AgNW rather than a metal sheet that can increase wear.

For example, conventional methods can cause oxidation damage on the AgNWs, e.g., via etching. These damaging effects can be prevented by the methods of the present embodiments by using room-temperature reactive sputtering with, for example, mixed Ar:N₂ gas flow at high chamber base pressures (0.5×10⁻⁴ Torr) to reduce the overall deposition costs. This can leverage residual H₂O from the sample and chamber to allow for oxynitride formation, with aluminum oxynitrides (AlOₓN_{y}) and zirconium oxynitrides (ZrOₓN_{y}) achieving approximately >1 Å/s deposition rates on glass and approximately >0.5 Å/s on poly(ethylene terephthalate) substrates. Once the solution-phase wires 102 are deposited thereon, a surface of the substrate 104 can include silver (Ag) and/or copper (Cu) nanowires. In some embodiments, the surface can include Ag and/or Cu nanotroughs, or lithographically patterned Ag or Cu micro- or nano-structures.

The target materials produced from the reactive sputtering process can be primarily oxides of the corresponding metals, with approximately 1% to about 7% of total N content (based on X-ray photoelectron spectroscopy analysis of deposited films on AgNW networks), as shown in Table 1, reproduced below:

TABLE 1
Surface composition (%) of oxynitride films deposited
on AgNW networks deposited on Si substrates, based
on XPS survey scans. Films vary in thickness approximately
in the range of about 20 nm to about 30 nm.

| Element | AlON | TiON | ZrON |
|---|---|---|---|
| Al | 35.81 | — | — |
| Ti | — | 26.52 | — |
| Zr | — | — | 24.49 |
| O | 55.47 | 50.52 | 53.89 |
| N | 1.39 | 6.18 | 4.70 |
| Ag | 0.00 | 3.35 | 0.82 |

Despite N₂ being used as the reactive gas, oxides can be expected to form at low temperatures and high base pressures due, at least in part, to the presence of O₂ and H₂O in the sputtering chamber and sample, which favor the formation of oxides because sputtered atoms can have kinetic energies that are high enough to access thermodynamically favorable oxidation states. Despite this condition, this method prevents oxidative damage of Ag. This can be justified by the fact that the ΔG_{f} of Ag₂O is higher than H₂O, which can prevent oxidation of the AgNW during the deposition process, while allowing deposited metals with lower ΔG_{f} to transform into oxynitrides. In principle, this approach can also be used to encapsulate CuNWs, where ΔG_{f} of CuO/Cu₂O is also higher than that of H₂O.

A pressure in the chamber 118 can vary. For example, the particles 114 can be deposited at a chamber base pressure that is approximately in a range from about 10⁻³ Torr to about 10⁻⁶ Torr and/or approximately in a range from about 10⁻⁴ Torr to about 10⁻⁵ Torr.

After deposition, these metal nanowire networks can demonstrate approximately a 15% reduction in linear resistance, which can be attributed to the vacuum and plasma inside the chamber 118. This can be attributable to the partial removal of poly(vinylpyrrolidone) (PVP), which is a non-conductive surface coating that can prevent agglomeration of AgNWs prior to deposition. Encapsulated AgNW networks can show a variety of improvements, depending, at least in part, on the coatings used, even at thicknesses of as little as 20 nm, as discussed above. Specifically, oxidative damage of Ag can be avoided, and can even be preserved, while the resistance does not increase as in conventional reactive sputtering processes using O₂ or other oxidative species as reactive gases. Rather, the resistance of the encapsulated AgNW networks of the present disclosure can decrease, as discussed above, thereby further distinguishing the present embodiments from conventional nanowire networks. Moreover, encapsulated AgNWs can show marked improvement of electrical, thermal, and/or chemical stability under harsh testing conditions, when compared to as-deposited networks. For example, TiOₓN_{y} can exhibit exceptional electrical stability, surviving at applied voltages up to about 7.87 V/cm (at a maximum areal power density of about 1.72 W/cm²) without resistance divergence (where unmodified AgNW networks fail at an average of 4.72 V/cm and an areal power density of about 0.95 W/cm²). Meanwhile, AlOₓN_{y} can exhibit a significant improvement in chemical stability, showing only about a 20% increase in linear resistance after over about 1000 hours (i.e., 40 days) under about 80° C., about 80% RH conditions (where unmodified AgNW networks exceed 1000% increase in linear resistance after about 36 hours, or about three (3) days). Additionally, or alternatively, ZrOₓN_{y}, (deposited using a Zr target, for example) can be used as a test material to prove that mechanical hardness can be used to drive materials design for encapsulants, at least because the Mohs hardness of ZrO₂ is between that of Al₂O₃ and TiO₂, which have a high and low hardness, respectively. This suggests that hard, non-hygroscopic materials can improve chemical stability, soft materials can have higher electrical stability, e.g., higher propensity to mitigate localized thermal stresses, and removal of the poly(vinylpyrrolidone) PVP coating can improve thermal stability, which is native to as-synthesized wires. In fact, the improved stability of the nanowire network after deposition can be used to obviate high-cost encapsulation technologies, which can be used for moisture and air-sensitive materials.

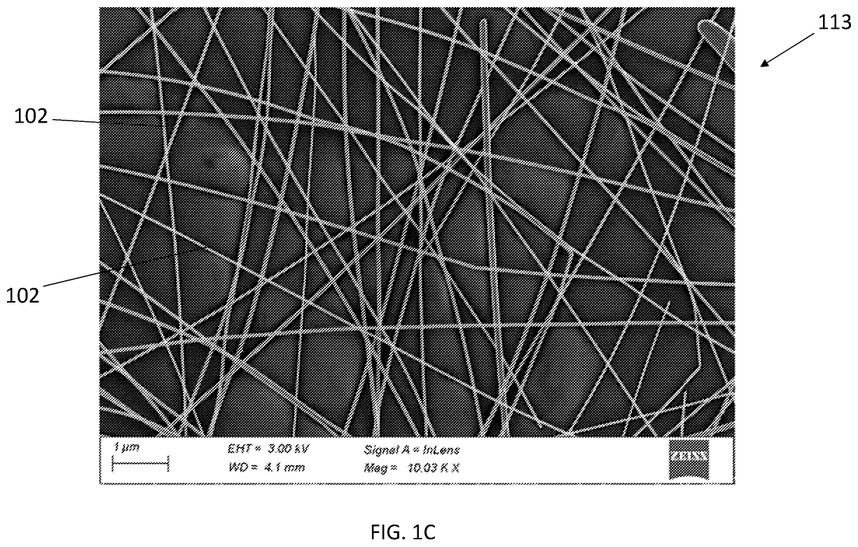

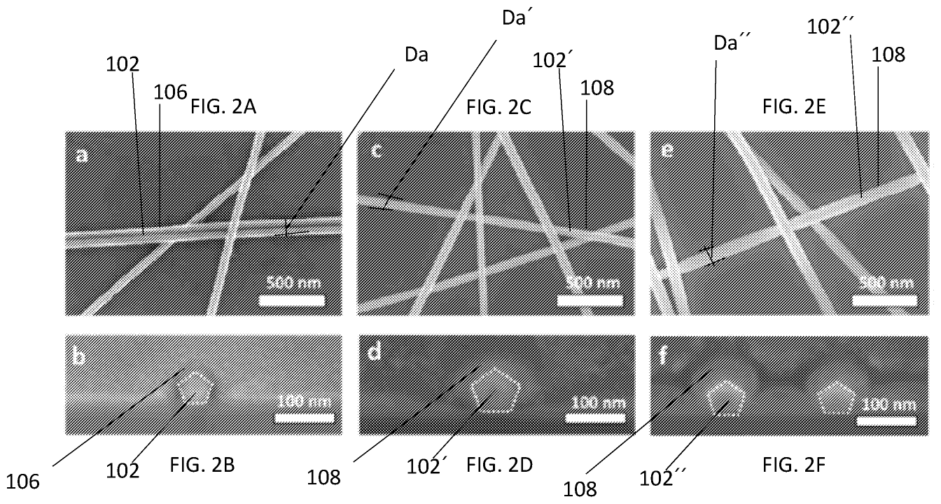

FIGS. 2A-2F illustrate surface scanning electron microscope (SEM) images of AlOₓN_{y}-coated wires 102, 102′, 102″, with the cross-sectional views prepared with focused-ion beam milling, and show a conformal coating around individual wires. Specifically, FIGS. 2A and 2B illustrate an untreated AgNW 102, FIGS. 2C and 2D illustrate an AgNW encapsulated in a 20 nm AlON film, and FIGS. 2E and 2F illustrate an AgNW encapsulated in a 50 nm AlON film. As shown, the encapsulated AgNWs 102′, 102″ can exhibit a slight increase in average diameter Da′ and Da″ as compared to the average diameter Da of the untreated AgNWs 102. Moreover, the residual PVP shell, an artifact of the deposition process (that is also used to suspend the AgNWs in solution), can be visible prior to sputtering, as shown in FIGS. 2B, 2D, and 2F. Once sputtering is complete, the PVP shell can be removed and replaced by the encapsulant 108 with the encapsulated AgNWs 102′, 102″ having a decreased resistance. The decrease in resistance, which is similar to other encapsulated samples shown in Table 2, can occur due to removing the PVP coating around the wire, which occurs due to the vacuum and plasma exposure inside the chamber:

TABLE 2
Linear resistance changes in samples from the sputtering process,
including percent variation in a triplicate of samples

| | Reduction in linear R | |
|---|---|---|
| Sample | [% (variation)] | |
| Bare Ag NW - Vacuum + Ar + | 12 | (3) |
| N₂ | | |
| AlON - 20 nm | 16 | (2) |
| AlON - 50 nm | 19 | (4) |
| ZrON - 20 nm | 15 | (4) |
| ZrON - 50 nm | 15 | (4) |
| TiON - 20 nm | 11 | (3) |
| TiON - 50 nm | 12 | (2) |

For TiON-coated samples, Ag nanoparticles can precipitate out of the coating even prior to harsh chemical stability testing. This can be attributed to the observed solubility and diffusivity Ag in TiO₂, and more specifically, the observed migration of Ag out of conformal TiO₂ coatings at high temperatures. In the case of ZrON and AlON-coated wires, this effect may not be observed, which can be correlated to higher bond strength, and which can be inversely related to interstitial diffusivity, as this is predominantly the proposed mechanism of Ag diffusion in oxides. The conformality of the coating can be confirmed through cross-section images, which illustrate the expected semi-conformal deposition profile from a sputter-deposited film. Notably, nanowire junctions that exist above the plane of the substrate 102 (which is common with as-deposited AgNW networks) can be susceptible to non-uniformity in film deposition, and thus, early junction failure. This can be mitigated with pre-annealing nanowire networks, though in the embodiments of the present disclosure, improvement in stability can be demonstrated despite these existing non-uniformities.

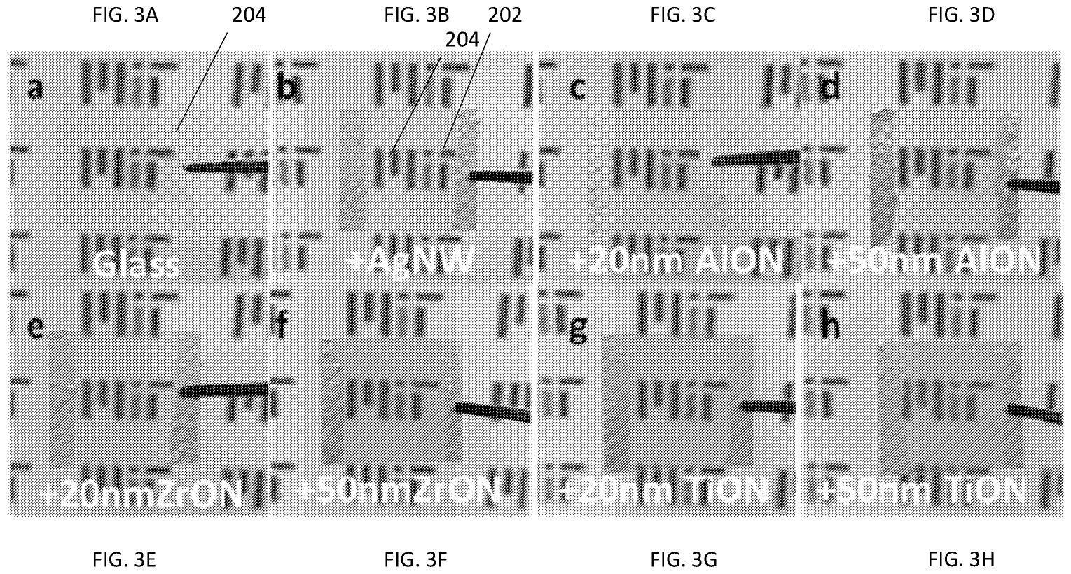

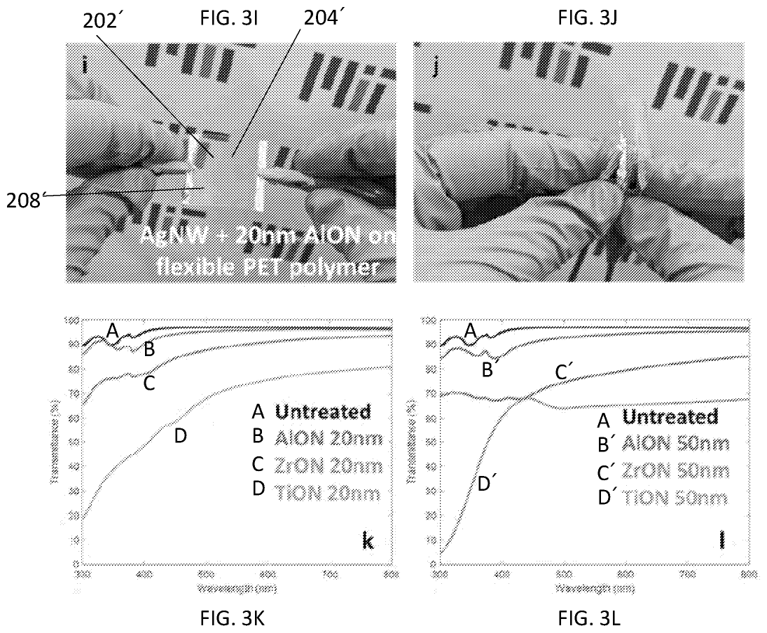

FIGS. 3A-3L illustrate the various embodiments of the encapsulated AgNW networks of the present embodiments in greater detail. For example, the AgNW networks of the transparent electrodes of the present embodiments can use sheet resistance and transparency metrics for transparent electrodes to indicate the functional and aesthetic properties in the end application, respectively. It will be appreciated that because the sheet resistance of AgNW films cannot be measured for encapsulated samples deposited on glass (due, at least in part, to the hardness and insulating nature of the encapsulant film), linear resistance can be used as a metric to establish electrical stability measurement.

Specifically, transparency of a glass substrate 204 is shown in FIG. 3A, while the glass substrate 204 having untreated AgNW 202 disposed on it is shown in FIG. 3B. As shown, transparency of the glass substrate 204 can be largely unaffected when the AgNW is disposed on the substrate 204.

The transparency of the encapsulated AgNW networks is shown in detail in FIGS. 3C-3H. As shown, application of a 20 nm film of AlON, ZrON, and TiON, illustrated in FIGS. 3C, 3E, and 3G, respectively, results in greater transparency in the TE as compared to 50 nm films of AlON, ZrON, and TiON, illustrated in FIGS. 3D, 3F, and 3H, respectively. Moreover, coloration changes of the TE can be observed for the 50 nm TiON film of FIG. 3G. Specifically, the 50 nm TiON film of FIG. 3H shows a noticeable blue hue resulting, at least in part, from the absorptive nature of the nitride species in the film, as well as observed Ag particle nucleation on the surface of the film post-deposition.

In some embodiments, the film 208′ can be deposited on a flexible substrate (PET) 204′ coated with AgNWs 202′. For example, the transparent electrode in FIG. 3I can include an AgNW 202′ that is encapsulated in 20 nm AlON film 208′ disposed on a flexible PET polymer 204′ substrate. In such embodiments, the flexible PET substrate 204′ can allow for several bending cycles, such as those shown in FIG. 3J, with minimal changes to the original resistance of the network at the un-bent state.

Uncoated and/or unencapsulated nanowire networks can exhibit failures in high surface nanostructures under applied current due to joule heating and exposure to atmospheric conditions. Transmittance spectra of the unencapsulated AgNW (A) and the AgNWs encapsulated with the 20 nm films (B, C, D) and 50 nm films (B′, C′, D′) are shown in FIGS. 3K and 3L, respectively. As shown, AlON shows the highest optical transmittance at both film thicknesses, followed by ZrON, followed by TiON across increasing wavelengths. Specifically, 20 nm AlON films (B) have lower transmittance for smaller wavelengths, with transmittances being substantially similar to untreated AgNW (A), while the transmittances for each of the 20 nm ZrON films (C) and 20 nm TiON films (D) are smaller throughout the range of wavelengths, e.g., 300 nm to 800 nm. Similar results can be observed for the 50 nm AlON film (B′), the 50 nm ZrON film (C′), and the 50 nm TiON film (D′), with the exception of lower transmittance values being observed for the 50 nm ZrON film (C′), and the 50 nm TiON film (D′). Moreover, the transmittance values for the 50 nm ZrON film (C′), and the 50 nm TiON film (D′) can be substantially similar at approximately 450 nm wavelengths.

As mentioned above, AgNW-based transparent conductors can be susceptible to atmospheric corrosion due, at least in part, to sulfidation, despite the very low concentrations of atmospheric sulfur-containing species such as H₂S and/or OCS. Sulfidation can be posited to occur through a combination of chemical reactions that can cause silver to form sulfates and sulfides through, for example, moisture-assisted corrosion mechanisms. These mechanisms can cause formation of semi-conducting particles on the surface of the nanowires 102, which can eventually lead to increases in nanowire resistance, and thus failure of the network. Encapsulants can play an important role in preventing this failure by delaying the arrival of atmospheric species to the coating surface. However, encapsulants can cause AgNWs to fail through diffusion of Ag through the encapsulant coating.

Moreover, when wires undergo Joule heating, they can fail due, at least in part, to differences in thermal expansion that can induce mechanical stresses. These stresses can promote stress-driven diffusion or mechanical defects that allow for short-circuit diffusion out of the encapsulation layer. However, in the case of chemical stability, the arrival of gases and acceleration of chemical processes due, at least in part, to moderate temperatures can cause failure, even in mild current densities (10 mA/cm² areal current density) relevant to photovoltaics applications. In view of this, performance testing of the encapsulated AgNWs can be performed at elevated humidity and/or moderate temperatures to simulate operation in tropical conditions to determine points of failure.

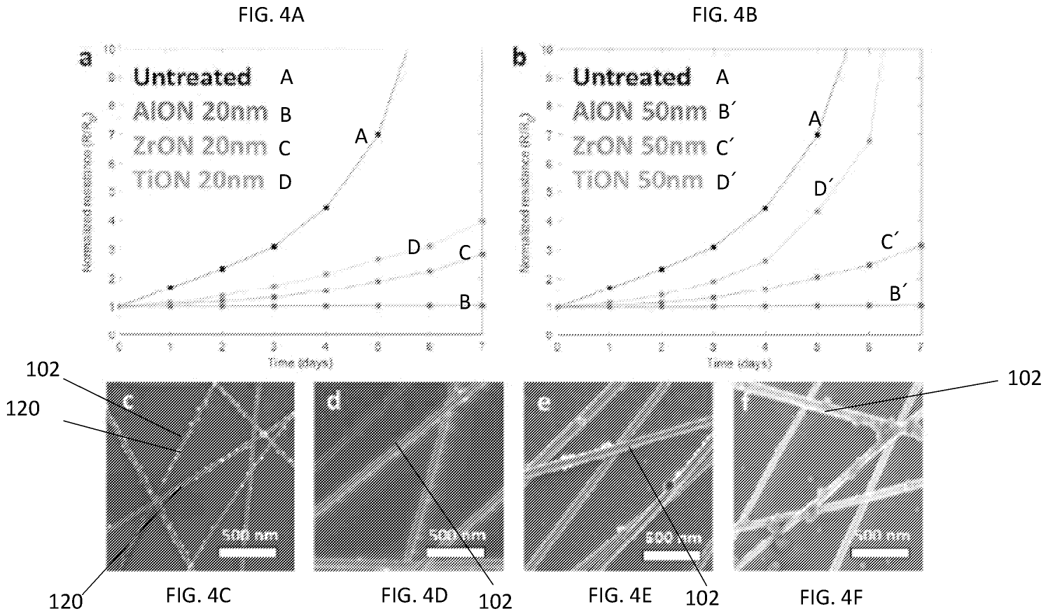

FIGS. 4A-4F illustrate the progression of linear resistance values for the unencapsulated AgNW (A) and the AgNWs encapsulated with the 20 nm films (B, C, D) and 50 nm films (B′, C′, D′). Resistance of the AgNW networks with and without treatment can be measured after several bending cycles (corresponding to about 2% maximum tensile strain). Unencapsulated and/or untreated AgNW networks on PET can show minimal resistance increase under applied strain, but their unbent resistance can increase gradually. Encapsulated networks can show significant increases in resistance when bent, which can be attributed, for example, to cracking of the encapsulated nanowire network under strain, but subsequently recover to close to their original value under removal of strain. This observed behavior of encapsulated AgNW networks can be a promising means of fabricating high-sensitivity strain sensors.

As previously mentioned, the plasma conditioning that can occur within the sputtering chamber 118 can lower the linear resistance of the networks by about 10% to about 20%. Four-point probe measurements cannot be carried out for samples on glass substrates 202, due, at least in part, to the hardness and thickness of the films preventing measurement of the underlying network, prompting the sheet resistance of networks before and after deposition to be confirmed on PET substrates 202′. This showed a similar reduction in sheet resistance at an average of about 11%. In some embodiments, the hardness of the encapsulant and solubility of Ag therein can govern the properties of the coatings, with high hardness being favorable for chemical stability, low hardness being favored for electrical stability, and no significant differences that govern thermal stability being observed, and which can be determined by the existence of a sufficiently thick and conformal encapsulant layer. In some embodiments, these encapsulant layers can potentially be further improved by implementing bilayer or multilayer coatings to simultaneously increase the electrical, thermal, and/or chemical stability beyond what it achievable with a single oxynitride film.

As shown in FIG. 4A, the normalized resistance in the 20 nm films can increase exponentially over time for the untreated film (A), while remaining substantially unchanged over time when encapsulated with AlON (B). The ZrON film (C) and the TiON film (D) can exhibit gradual increases in normalized resistance, as shown. The relative behaviors for the encapsulated 50 nm films can exhibit similar behavior. As shown in FIG. 4B, the normalized resistance in the 50 nm AlON film (B) can remain substantially unchanged over time. Meanwhile, the 50 nm ZrON film (C) can show an increase in resistance similar to that of the 20 nm ZrON film (C), and the 50 nm TiON film (D′) can exhibit a gradual increase in resistance over the first about four (4) days, and then can increase exponentially over time.

Resistance values can change in response to, for example, harsh chemical testing conditions, as discussed above. For example, the impact of testing on the AgNW are shown in greater detail in FIGS. 4C-4F. As shown, after about six (6) days, untreated AgNW network samples can display signs of sulfidation, through the formation of characteristic Ag₂S particles 120 on the surface, as shown in FIG. 4C. ZrON coated AgNWs can show moderate increase in normalized resistance after about seven (7) days, with a negligible difference in performance between the 20 nm-thick and the 50 nm-thick encapsulant with few visible particles on the surface, as shown in FIG. 4D. TiON samples show little improvement in chemical stability of nanowires, as shown in FIG. 4E, likely due, at least in part, to the high solubility of Ag in TiO₂, which can be exacerbated at higher thicknesses due to, for example, a higher capacity for the coating to leach Ag from the nanowires. For both TiON samples and ZrON samples, particles can tend to be more focused around junction areas, which implies that areas of higher curvature have a higher propensity to react with atmospheric species, in addition to being more likely to have defects in the coating due, at least in part, to shadowing effects during film deposition.

AlON-coated nanowires can exhibit average resistance increases of about 4% and about 6% for 20 nm and 50 nm coated wires for the first seven (7) days, respectively. These samples can show about 25% and about 19% total resistance increase, respectively, after about forty-two (42) days of testing, which can exceed the performance of unencapsulated wires even after one (1) day. For AlON-coated nanowires, particles can form on the surface after about 40 days of testing, as shown in FIG. 4F, yet these particles can be scattered across the wires 102 and the substrate 104. This indicates reactant diffusion through the coating, rather than short-circuit diffusion, which is also indicated by the linear increase, as opposed to an exponential increase, in the linear resistance over about 40 days. These conditions can be analogous to the 1000 Damp Heat test, a test designed to evaluate the long-term stability of photovoltaic modules in high humidity conditions and understood by a person skilled in the art. In previous long-term stability module tests, primarily failure modes have been through the moisture penetrating the module encapsulation and damaging the metal and conductive oxide. Use of the coatings and encapsulation methods of the present embodiments can demonstrate that they can mitigate such a failure mode at the nanowire level.

### Thermal and Electrical Stability

The thermal stability of nanowire networks can be accounted for in transparent heater applications. The electrical stability of a nanowire network can be closely linked to its thermal stability with added focus on the ability of the nanowires to prevent the propagation of localized thermal failure, known as a hotspot, which can lead to runaway failure.

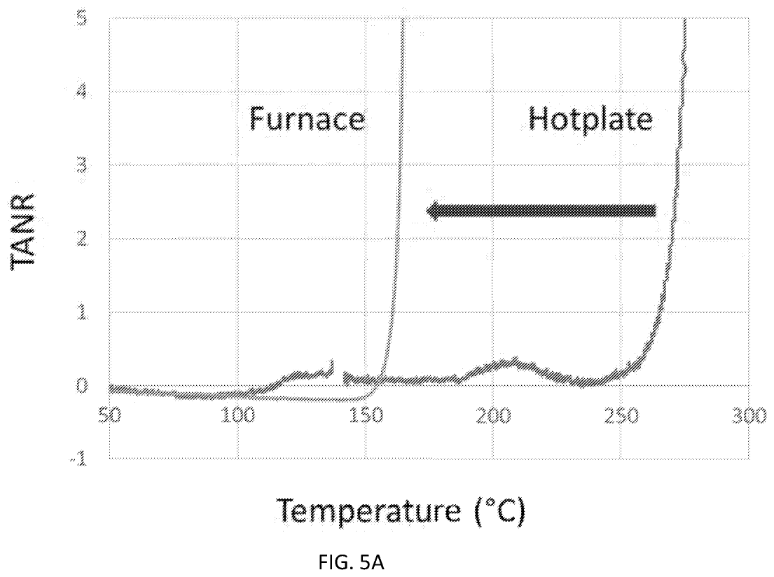

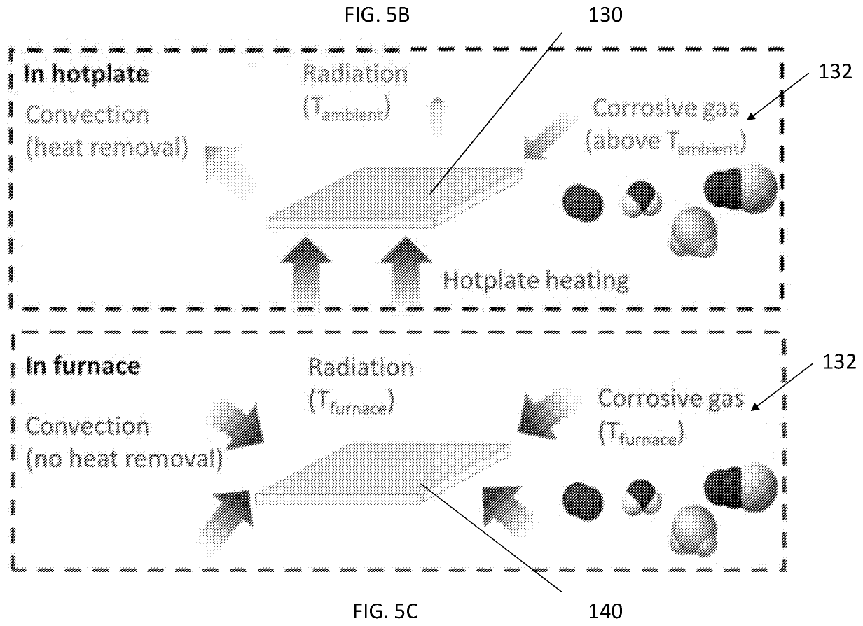

In addition to the effect that the encapsulant film can have on the thermal stability of the nanowires, a comparison of furnace-heated and hotplate-heated nanowires is shown in greater detail in FIGS. 5A-5C. As shown in FIG. 5A, measurements of temperature versus Thermally-Adjusted Normalized Resistance (TANR) values for samples tested under furnace heating showed failure at approximately 100° C. below the expected failure point in the furnace.

FIGS. 5B and 5C illustrate the differences between hotplate heating and furnace heating. As shown in FIG. 5B, a hotplate 130 can be heated and encounter by a corrosive gas 132 at above ambient temperature. Heat can be removed from the hotplate 130, for example via convection, and/or ambient heat can also escape via radiation. The thermal test, which can be an in-situ ramp performed in an open tube furnace (e.g., in air), as discussed in greater detail below, can demonstrate the overall stability of the nanowire network. The nanowire network can have a uniform thermal stress applied across the network. This test can consider the failure mode to be when the entire sample—including substrate and all nanowires in the network—are heated to the same temperature to experience uniform thermal stresses from the substrate, encapsulant film, and nanowires. In the case that the nanowires are heated from one side of the sample, and/or in Joule heating, nanowires can expel heat through radiation and/or convection with the ambient environment. In the case of Joule heating, nanowires can dissipate heat into the substrate, which can act as a large thermal sink. Lastly, the ambient air can be much lower than the thermal source temperature (due, at least in part, to convection), which can invariably affect the morphological evolution and/or the chemical evolution of nanowires.

In the case of the tube furnace testing 140, as shown in FIG. 5C, none of these mechanisms are available to dissipate heat away from the nanowires because the entire furnace area is at, or substantially at, the target temperature. One skilled in the art will recognize that tube furnaces can be modified to run the presently disclosed processes while having the unique characteristic that because the tube furnace does not have a controlled gas environment (such as inert gas flow), electrically probing the sample live during the heating, e.g., the technique of measuring the resistance change live during tube furnace heating, may not be available. Moreover, the air in the furnace 140 can be at the furnace temperature, which can imply a harsher testing environment, more reflective of encapsulated Joule heaters or photovoltaic electrodes in the middle of a stack where adjacent layers can reach moderately high temperatures during operation. To evaluate the thermal stability of the nanowire networks, the figure of merit used is called the Thermally-Adjusted Normalized Resistance (TANR) value, as denoted in Equation 1:

$$T A N R = \frac{R}{{R}_{0}} - ( 1 + {β}_{t} \cdot Δ T ) \qquad ( 1 )$$

In this Equation, R/R₀ represents the ratio between the current and initial linear resistance and βₜ represents the thermal coefficient of resistivity (in K⁻¹), where silver has a reported bulk value of 3.8·10-3 K⁻¹. Though nanowire networks can exhibit lower βₜ values than bulk, the bulk value can be used here for simplicity because it represents a minor offset close to failure, where R/R₀ diverges. AT can represent the change in temperature between R and R₀. The TANR value can represent the degree of irreversible evolution of a material. Assuming a polycrystalline metal far below its melting point, this value can typically remain at 0. When the value goes below 0 non-monotonically, this can represent an optimization of the conductive pathways of the network (in the case of nanowire networks, this represents junction optimization). When the value is greater than 0, this can indicate irreversible morphological evolution of the network attributed to junction failure and spheroidization.

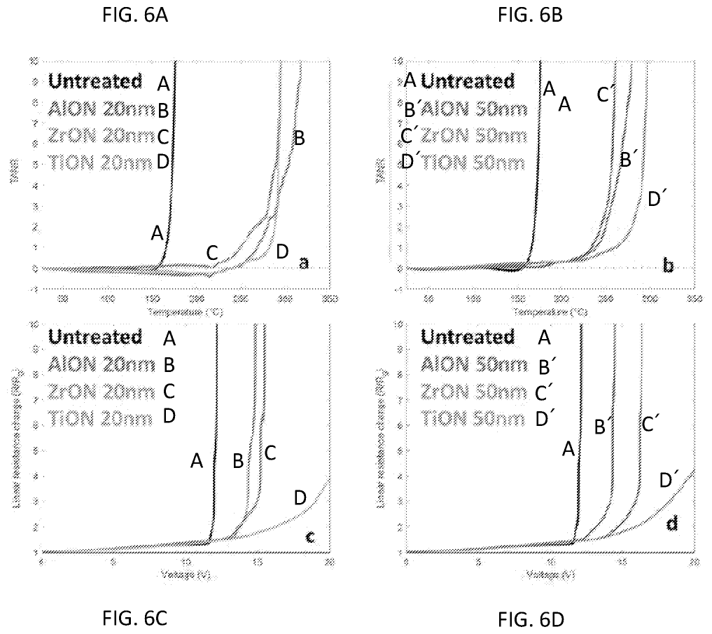

With as little as 20 nm of film, a thermal stability improvement of over 100° C. under a harsh furnace environment, chemical stability for over about 1000 hours of about 80° C./about 80% RH conditions, and electrical stability with applied linear voltages of about 7.87 V/cm can be demonstrated with the coatings of the present disclosures. For example, FIGS. 6A-6D illustrate the evolution of the electrical resistance of the nanowire network as a function of the furnace temperature for 20 nm films (FIGS. 6A and 6C) and 50 nm films (FIGS. 6B and 6C) with representative plots. Specifically, FIGS. 6A and 6B illustrate TANR values of AgNW networks that are untreated (A), and thermally ramped at 6.25° C./min, as compared with those encapsulated with 20 nm AlON film (B), 20 nm ZrON film (C), 50 nm TiON film (D), 50 nm AlON film (B), 50 nm ZrON film (C), and 50 nm TiON film (D′). Given the relatively high variability in sample failure temperatures for encapsulated wires, which can be attributed, at least in part, to slight differences in junction morphologies and network connectivity, adding an encapsulant film onto the nanowires can increase the thermal stability to around 100° C. above the expected failure point, as shown. Notably, the increase in film thickness does not typically improve the nanowire network thermal stability. This can be attributed to defect-induced failure and diffusion of Ag. Moreover, because the thermal expansion of oxides can be roughly half of that of Ag, in addition to the Young's modulus being much higher, the encapsulant coating can induce compressive stresses on the nanowire. This can be caused, at least in part, by thermal expansion mismatch, which can cause cracks in the encapsulant layer and delamination of wires from the substrate.

Electrical testing can show the robustness of the network to runaway failure modes, where thermal stresses are concentrated at areas of high nanowire connectivity. High nanowire connectivity can be located in the approximate center of the sample for contacts painted on two edges of the sample, thereby contributing to the hottest part of the sample being initially close to the center. As the voltage is increased, bare nanowires can fail at a significantly lower temperature than encapsulated wires. FIGS. 6C-6D illustrate normalized resistance of AgNW networks as compared to untreated wires, ramped at about 0.5 V/min. Notably, both AlON films (B′) and ZrON film (C′) fail at lower voltages than TiON films (D′). Among these films, the TiON film (D′) does not show resistance divergence even up to about 20 V across the sample, which counters the earlier trend that shows its poor chemical performance. Similarly, as shown, the AlON film (B′), which showed the best chemical resistance, shows the poorest electrical stability as a function of linear voltage supplied.

This phenomenon can be justified by considering that as an electrical load is applied across the sample, the most conductive regions carry higher currents. Additionally, local areas of lower densities (such as areas that do not contain nanowires due, at least in part, to substrate contamination and/or nanowire contaminants, for example) can cause adjacent regions to take on higher current densities due, at least in part, to redirection of current. A combination of these conditions can cause thermal crack propagation to occur. To circumvent this issue, electrical and/or thermal co-percolation can used to redirect current and/or heat away from local hotspots. The ability of a network to survive high electrical loads can depend, at least in part, on its ability to direct current away from its hotspot to mitigate runaway crack propagation, especially in the case of voltage ramping, which further accelerates the failure process.

Analysis of thermal distributions across samples of AgNW networks under moderate applied voltages (e.g., 10 V) and near failure conditions illustrate that failure can occur through the thermal crack propagation mechanism, as mentioned above, which can show a more evenly distributed temperature profile compared to unencapsulated wires. In the case of TiON, the samples can include a levelling-off of the maximum temperature as a function of applied voltage, while the average temperature increases. For AlON and ZrON films, the maximum temperatures can increase rapidly and spike when the crack is formed, at which point the average temperature can decrease, indicating degradation of the network. This phenomenon suggests that Ag can diffuse into the TiON coating at the local hotspots, which can increase the local resistance of the sample, and promotes delayed failure. For example, this increase in resistance can allow the current to be redirected to adjacent areas without current crowding, which would typically exacerbate joule heating-driven thermal crack propagation. Unlike typical runaway failure mode, the TiON sample can undergo a more gradual increase in resistance, with little damage to the overall electrical properties of the network. Partial distribution of the hotspot load can also be seen with AlON and ZrON samples compared to the untreated nanowire sample. The conditioned sample (one that has undergone the sputtering process with a closed sputtering gun shutter) can have larger “hotspots,” which can be attributed to more homogeneous junction resistances and can allow for a better distribution of thermal loading while still failing at a relatively low voltage and maximum temperature. This can be due, at least in part, to the lack of an encapsulant coating to prevent diffusion. TiON can therefore be used in applications such as transparent heating where high linear voltages are desired.

Physical properties such as diffusivity of the nanowire material in the encapsulant, as well as hardness, can play a role in selecting an appropriate coating. Further, reactive sputtering can be viable at high base pressures, which can still produce high-quality films using full-metal targets that may be of interest for current processing in industry. In photovoltaics applications, magnetron sputtering, despite its high capital costs, can be used to manufacture key components in solar cells due, at least in part, to the high potential throughput. Especially in the context of manufacturing, throughput can be an important consideration at least because a significant disadvantage for solution-processed (especially aqueous) components is the potential to require extensive drying times. Moreover, the films of the present embodiments can act as encapsulants, and they may obviate the use of expensive composite nanolaminates, which significantly reduces costs of manufacture as compared to conventionally sputtering a 200 nm Indium Zinc Oxide (IZO) transparent electrode.

### EXAMPLES

### Fabrication of AgNW/Oxynitride Transparent Electrode

An AgNW suspension (average diameter, about 50 nm; length, approximately in the range of about 100 to about 200 μm) in isopropanol, can be acquired from ACS Material, and can be diluted in isopropanol to a concentration of about 1 mg/mL. Corning® Eagle XG alkaline earth boro-aluminosilicate glass substrates can be obtained from Delta Technologies. In preparation for deposition, the substrates can be cleaned through ultrasonication in, for example, acetone, isopropanol, and deionized water, then dried with N₂ gas. Then they can be treated with UV/Ozone for about 15 minutes. The cleaned substrates can be spin-coated at about 1200 rpm to form the AgNW network.

Flexible AgNW networks can be prepared on approximately 125 μm-thick poly(ethylene terephthalate) substrates (Tekra Corporation), which can be ultrasonicated in isopropanol and deionized water. Then substrates can be treated with UV/Ozone for about 15 minutes. Aqueous 0.1% w/v poly(L-lysine) (Sigma-Aldrich) can then be deposited onto the substrate, for example to improve AgNW adhesion. Then, AgNW solution (e.g., about 2.0 mg/mL) can be spin-cast onto the substrate.

To encapsulate AgNW networks, samples can be sputtered with oxynitride, for example having a thickness approximately in the range of about 20 nm to about 50 nm, using reactive sputtering and metal targets in an Orion 5 3-target sputtering system (AJA International). All deposition can be initiated at about 0.5×10⁻⁴ Torr base pressure. For Al and Zr, deposition can be carried out, for example, at about 195 W with intermittent arc DC sputtering, with about 8 sccm Ar and about 4 sccm N₂ (totaling about 12 sccm gas flow), with a deposition pressure of about 1.8 mTorr. For Ti, deposition can be carried out, for example, at about 195 W with RF sputtering (e.g., 13.56 MHZ) with about 9.9 sccm Ar and about 2.1 sccm N₂ (totaling about 12 sccm gas flow), with a deposition pressure of about 3.0 mTorr. Deposition rate can be measured with a quartz crystal microbalance at deposition height prior to sputtering. Prior to deposition, all targets can be pre-sputtered, for example at about 100 W for about 10 minutes with about 12 sccm Ar flow at about 3 mTorr deposition pressure.

UV-Visible spectra can be obtained from a PerkinElmer LAMBDA 1050 UV/Vis/NIR Spectrophotometer with an Integrating Sphere. AgNW morphology can be evaluated with Scanning Electron Microscopy (Hitachi SU-8100), and cross-sectional imaging can be performed with a Helios 660 SEM-FIB Dual Beam system. Prior to cross-section preparation, the sample can be locally coated with electron-beam deposited C (about 20 nm) and Pt (about 500 nm) to protect the surface during the etching process. Surface chemical characterization was done using X-ray Photoelectron Spectroscopy (Thermo-Fischer Nexsa XPS).

### Chemical, Thermal, and Electrical Stability Studies

Testing can involve measuring the electrical resistances across the transparent electrodes. Silver paste contacts can be applied on two opposite edges of each of the samples, with silver paste (DuPont 4922N-100) acquired from Delta Technologies. Samples can be cleaved in half for the chemical and thermal tests. Prior to testing, sheet resistance of samples can be measured, for example, using a four-point probe measurement, confirming that all samples are approximately in a range of about 15 Ω/sq to about 25 Ω/sq.

Chemical Test: Chemical stability can be evaluated under accelerated degradation conditions, for example by placing samples on a hotplate (e.g., Torrey Pines HP60A) at about 80° C., inside an environmental chamber (e.g., 5533 environmental chamber by Electro-Tech Systems Inc.) set to 80% RH and their linear resistance can be measured once a day for about seven (7) days. For 20 nm- and 50 nm-coated AlON samples (which showed only a 4% to about a 6% increase in normalized linear resistance after seven (7) days of testing), measurement can be continued for over 40 days (e.g., >1000 hours) and measured every few days.

Thermal Test: Samples can be placed individually in a tube furnace (e.g., Lindberg/Blue M™ 1200° C.) which can be ramped up from about 25° C. to about 400° C. over the span of an hour. Sample resistance can be measured every second using, for example, a Keithley 2401 source meter unit (SMU) and Lab View program.

Electrical Test: Electrical stability can be assessed in-situ using, for example, a Keithley 2401 SMU. A LabView program that interfaces with the SMU can deliver a voltage to the samples. The voltage can be ramped from about 0 V up to about 20 V at a rate of approximately 0.5 V/min, while sample resistance can be measured. A FLIR A615 infrared camera can be used to map the temperature across the sample throughout the voltage ramp. Sample emissivity values can be estimated by heating samples on a hotplate and calibrating the observed temperatures with respect to a piece of glass of known emissivity.

Examples of the above-described embodiments can include the following:

1. An electrode device, comprising:
a substrate material;
a solution-phase wire material; and
an encapsulant film disposed on a surface of the solution-phase wire material, the encapsulant film comprising a sputtered oxynitride, the sputtered oxynitride including a metal and nitrogen,
wherein a linear resistance of the solution-phase wire material having the encapsulant film disposed on its surface is less than a linear resistance of the solution-phase wire material having no encapsulant film disposed on its surface.

2. The electrode device of example 1, wherein a thermal stability of the electrode device is approximately 100° C. above a failure point of an electrode device that lacks an encapsulant film disposed on a surface of the solution-phase wire material.

3. The electrode device of example 1 or example 2, wherein the substrate material comprises one or more of glass, silicon, or polyethylene terephthalate (PET).

4. The electrode device of any of examples 1 to 3, wherein a form factor of the solution-phase wire material is approximately in a range of about 20 nm to about 200 nm.

5. The electrode device of any of examples 1 to 4, wherein the solution-phase wire material contains one or more of Ag or Cu nanowires, Ag or Cu nanotroughs, or lithographically patterned Ag or Cu micro- or nano-structures.

6. The electrode device of any of examples 1 to 5, wherein a thickness of the encapsulant film is approximately in a range of about 0 nm to about 100 nm.

7. The electrode device of any of examples 1 to 6, wherein the oxynitride comprises one or more of AlOₓN_{y}, TiOₓN_{y}, or ZrOₓN_{y}.

8. The electrode device of any of examples 1 to 7, wherein a percentage of the nitrogen in the encapsulant film is approximately in a range of about 0% of a total atomic composition of the film to about 30% of a total atomic composition of the film.

9. The electrode device of any of examples 1 to 8, wherein an electrical stability with applied linear voltages for the electrode device is about 7.87 V/cm without resistance.

10. The electrode device of any of examples 1 to 9, wherein an electrical stability with applied linear voltages for the electrode device is approximately 1.66 times larger than an electrode device that lacks an encapsulant film disposed on a surface of the solution-phase wire material.

11. The electrode device of any of examples 1 to 10, wherein a chemical stability of the electrode device has an increase in linear resistance that is approximately fifty times smaller than an electrode device that lacks an encapsulant film disposed on a surface of the solution-phase wire material.

12. A method of manufacturing a transparent electrode, comprising:
sputtering a metal target material with one or more gases, at least one of which includes nitrogen, in a sputtering chamber to eject one or more solid particles of the metal target material;
reacting the one or more solid particles with the one or more gases to form a resulting material; and
depositing the resulting material onto a substrate having one or more nanowires disposed thereon, the resulting material forming a film when deposited onto the substrate having one or more nanowires disposed thereon,
wherein the resulting material conforms to one or more of the substrate or the nanowires to surround the one or more of the substrate or the nanowires at least across a circumference of the nanowires.

13. The method of example 12, wherein the resulting material is directly deposited onto one or more of the substrate or the nanowires as an encapsulant configured to prevent damage thereto.

14. The method of example 12 or example 13, wherein the resulting material is deposited using residual water vapor in the sputtering chamber.

15. The method of any of examples 12 to 14, wherein the sputtering occurs at high base pressures to leverage the residual water vapor on at least one of the nanowires or within the sputtering chamber.

16. The method of example 15, wherein the high base pressures are approximately in a range of about 10⁻³ to about 10⁻⁶ Torr.

17. The method of any of examples 12 to 16, wherein the one or more gases comprise one or more of argon (Ar), nitrogen (N₂), oxygen (O₂^{¬}), or water (H₂O).

18. The method of any of examples 12 to 17, further comprising conditioning the nanowires prior to sputtering by removing a portion of one or more compounds from a surface thereof.

19. The method of example 16, wherein the one or more compounds comprises poly(vinylpyrrolidone) (PVP).

20. The method of example 18 or example 19, wherein conditioning comprises at least one of vacuum or plasma exposure.

21. The method of any of examples 12 to 20, wherein the metal target comprises one or more of aluminum (Al), titanium (Ti), zirconium (Zr), zinc (Zn), hafnium (Hf), silicon (Si), metalloids, semiconductors, alloys, or combinations thereof.

22. The method of any of examples 12 to 21, wherein the resulting material is deposited with a substrate temperature approximately in the range of about 298 K to about 900 K.

23. The method of claim any of examples 12 to 22, wherein the resulting material is deposited with no external heating applied to the substrate.

24. The method of any of examples 12 to 24, wherein sputtering further comprises one or more of direct-current sputtering, reactive magnetron sputtering, radio-frequency magnetron sputtering, or intermittent arc DC sputtering.

25. An electrode device, comprising:
a substrate material;
a solution-phase wire material; and
an encapsulant film applied to the solution-phase wire material, the encapsulant film comprising an oxynitride formed by sputtering a metal target with nitrogen gas, the film forming on a surface of the solution-phase wire material when applied thereto,
wherein a linear resistance of the solution-phase wire material having the encapsulant film applied thereto decreases after the encapsulant film is applied thereto.

26. The electrode device of example 20, wherein a thermal stability of the electrode device is approximately 100° C. above a failure point of an electrode device that lacks an encapsulant film disposed on a surface of the solution-phase wire material.

27. The electrode device of example 20 or example 26, wherein the substrate material comprises one or more of glass, silicon, or polyethylene terephthalate (PET).

28. The electrode device of any of examples 25 to 27, wherein a form factor of the solution-phase wire material is approximately in a range of about 20 nm to about 200 nm.

29. The electrode device of any of examples 25 to 28, wherein the solution-phase wire material contains one or more of Ag or Cu nanowires, Ag or Cu nanotroughs, or lithographically patterned Ag or Cu micro- or nano-structures.

30. The electrode device of any of examples 25 to 29, wherein a thickness of the encapsulant film is approximately in a range of about 0 nm to about 100 nm.

31. The electrode device of any of examples 25 to 30, wherein the oxynitride comprises one or more of AlOₓN_{y}, TiOₓN_{y}, or ZrOₓN_{y}.

32. The electrode device of any of examples 25 to 31, wherein a percentage of the nitrogen in the encapsulant film is approximately in a range of about 0% of a total atomic composition of the film to about 30% of a total atomic composition of the film.

33. The electrode device of any of examples 25 to 32, wherein an electrical stability with applied linear voltages for the electrode device is about 7.87 V/cm without resistance.

34. The electrode device of any of examples 25 to 33, wherein an electrical stability with applied linear voltages for the electrode device is approximately 1.66 times larger than an electrode device that lacks an encapsulant film disposed on a surface of the solution-phase wire material.

35. The electrode device of any of examples 25 to 34, wherein a chemical stability of the electrode device has an increase in linear resistance that is approximately fifty times smaller than an electrode device that lacks an encapsulant film disposed on a surface of the solution-phase wire material.

One skilled in the art will appreciate further features and advantages of the disclosures based on the provided for descriptions and embodiments. Accordingly, the inventions are not to be limited by what has been particularly shown and described. All publications and references cited herein are expressly incorporated herein by reference in their entirety.

Some non-limiting claims that are supported by the contents of the present disclosure are provided below.

What is claimed is:

1. An electrode device, comprising:
a substrate material;
a solution-phase wire material; and
an encapsulant film disposed on a surface of the solution-phase wire material, the encapsulant film comprising a sputtered oxynitride, the sputtered oxynitride including a metal and nitrogen,
wherein a linear resistance of the solution-phase wire material having the encapsulant film disposed on its surface is less than a linear resistance of the solution-phase wire material having no encapsulant film disposed on its surface.

2. The electrode device of claim 1, wherein a thermal stability of the electrode device is approximately 100° C. above a failure point of an electrode device that lacks an encapsulant film disposed on a surface of the solution-phase wire material.

3. The electrode device of claim 1, wherein the substrate material comprises one or more of glass, silicon, or polyethylene terephthalate (PET).

4. The electrode device of claim 1, wherein a form factor of the solution-phase wire material is approximately in a range of about 20 nm to about 200 nm.

5. The electrode device of claim 1, wherein the solution-phase wire material contains one or more of Ag or Cu nanowires, Ag or Cu nanotroughs, or lithographically patterned Ag or Cu micro- or nano-structures.

6. The electrode device of claim 1, wherein a thickness of the encapsulant film is approximately in a range of about 0 nm to about 100 nm.

7. The electrode device of claim 1, wherein the oxynitride comprises one or more of AlOₓN_{y}, TiOₓN_{y}, or ZrOₓN_{y}.

8. The electrode device of claim 1, wherein a percentage of the nitrogen in the encapsulant film is approximately in a range of about 0% of a total atomic composition of the film to about 30% of a total atomic composition of the film.

9. The electrode device of claim 1, wherein an electrical stability with applied linear voltages for the electrode device is about 7.87 V/cm without resistance.

10. The electrode device of claim 1, wherein an electrical stability with applied linear voltages for the electrode device is approximately 1.66 times larger than an electrode device that lacks an encapsulant film disposed on a surface of the solution-phase wire material.

11. The electrode device of claim 1, wherein a chemical stability of the electrode device has an increase in linear resistance that is approximately fifty times smaller than an electrode device that lacks an encapsulant film disposed on a surface of the solution-phase wire material.

12. A method of manufacturing a transparent electrode, comprising:
sputtering a metal target material with one or more gases, at least one of which includes nitrogen, in a sputtering chamber to eject one or more solid particles of the metal target material;
reacting the one or more solid particles with the one or more gases to form a resulting material; and
depositing the resulting material onto a substrate having one or more nanowires disposed thereon, the resulting material forming a film when deposited onto the substrate having one or more nanowires disposed thereon,
wherein the resulting material conforms to one or more of the substrate or the nanowires to surround the one or more of the substrate or the nanowires at least across a circumference of the nanowires.

13. The method of claim 12, wherein the resulting material is directly deposited onto one or more of the substrate or the nanowires as an encapsulant configured to prevent damage thereto.

14. The method of claim 12, wherein the resulting material is deposited using residual water vapor in the sputtering chamber.

15. The method of claim 12, wherein the one or more gases comprise one or more of argon (Ar), nitrogen (N₂), oxygen (O₂^{¬}), or water (H₂O).

16. The method of claim 12, further comprising conditioning the nanowires prior to sputtering by removing a portion of one or more compounds from a surface thereof.

17. The method of claim 16, wherein conditioning comprises at least one of vacuum or plasma exposure.

18. The method of claim 12, wherein the metal target comprises one or more of aluminum (Al), titanium (Ti), zirconium (Zr), zinc (Zn), hafnium (Hf), silicon (Si), metalloids, semiconductors, alloys, or combinations thereof.

19. The method of claim 12, wherein the resulting material is deposited with a substrate temperature approximately in the range of about 298 K to about 900 K.

20. An electrode device, comprising:
a substrate material;
a solution-phase wire material; and
an encapsulant film applied to the solution-phase wire material, the encapsulant film comprising an oxynitride formed by sputtering a metal target with nitrogen gas, the film forming on a surface of the solution-phase wire material when applied thereto,
wherein a linear resistance of the solution-phase wire material having the encapsulant film applied thereto decreases after the encapsulant film is applied thereto.
